(19) United States
(12) Patent Application Publication
(10) Pub. No.: US 2007/0037322 A1
(43) Pub. Date: Feb. 15, 2007

(54) End electrode structure of a surface-mounted resettable over-current protection device

(75) Inventors: Chien-Hao Huang, Zhunan Town (TW); Wen-Chih Li, Zhunan Town (TW)

Correspondence Address: Ladas & Parry LLP, 26 West 61st Street, New York, NY, 10023, US

(73) Assignee: INPAQ TECHNOLOGY CO., LTD.

(21) Appl. No.: 11/373,787

(22) Filed: Mar. 10, 2006

(30) Foreign Application Priority Data
Aug. 10, 2005 (TW) 094213687

(51) Int. Cl. H01L 21/82

(52) U.S. Cl. 438/128

(57) ABSTRACT

The present invention relates to an end electrode structure of a surface-mounted resettable over-current protection device. A polymer-based sheet is punched with a mold for manufacturing a plurality of H-shaped through-holes separated at an equal interval, such that several strip-shaped sheets are formed. Then, a first pair of electrodes and a second pair of electrodes are manufactured on each of the strip-shaped sheets through an ordinary through-hole manufacturing process of a printed circuit board. Then, the sheet is divided into several strip-shaped devices, thereby forming several over-current protection devices with five-sided electrodes. Thereby, with the five-sided electrode, the device may be more easily adhered to a circuit board.

### FIELD OF THE INVENTION

The present invention relates to an end electrode structure of a surface-mounted resettable over-current protection device, and more particularly, to an over-current protection device with a five-sided electrode, such that the device can be more easily adhered to a circuit board.

### DESCRIPTION OF THE PRIOR ART

According to a conventional resettable over-current protection device, such as ROC Patent Application No. 092115677, entitled “Resettable Over-current Protection Device and Manufacturing Method Thereof”, it discloses a material with variable resistance, which includes: an upper surface, a lower surface, a left end surface, and a right end surface; an upper main structural electrode disposed on the upper surface and having an upper trench for exposing the material; a lower main structural electrode disposed on the lower surface; an upper insulating layer covering a portion of the upper main structural electrode and the upper trench; a lower insulating layer covering a portion of the lower main structural electrode; a first left connection layer covering a portion of the left end surfaces of the material and covering the upper main structural electrode and the lower main structural electrode adjacent to the left end surface, thereby electrically connecting the upper and lower main structural electrodes; a first right connection layer covering the upper main structural electrode adjacent to the right end surface; a second left connection layer cladding the first left connection layer to act as a first connection terminal; a second right connection layer covering the first right connection layer to act as a second connection terminal.

However, as for this prior patent application, the operation is simplified, consumption of resources is reduced, and the electrode structure is not easily damaged during subsequent manufacturing steps, but the electrodes will not be manufactured until the device has been completely tailored, resulting in difficulties for manufacturing electrodes on devices of a small area, which results in higher manufacturing costs and does not meet a economical requirement.

### SUMMARY OF THE INVENTION

In view of the disadvantages in the prior art, the inventors exert their efforts to research a variety of methods to solve the foregoing disadvantages, based on manufacturing experience and technical accumulation about the over-current protection device. After persistent investigations, experiments, and improvements, an innovative end electrode structure of a surface-mounted resettable over-current protection device of the present invention finally has been designed and developed, thereby getting rid of the disadvantages of the prior art.

An object of the present invention is to provide an end electrode structure of an surface-mounted resettable over-current protection device, such that the device can be more easily adhered to the circuit board.

According to the aforementioned object, the structure is formed by the following steps. A polymer-based sheet is punched through a mold for manufacturing a plurality of H-shaped through-holes arranged at equal intervals, thereby forming several strip-shaped sheets. Then, a first pair of electrodes and a second pair of electrodes are manufactured on each of the strip-shaped sheets through an ordinary through-hole manufacturing process of a printed circuit board. Later, the sheet is divided into several strip-shaped devices, thereby forming several over-current protection devices with five-sided electrodes. Through the five-sided electrode, it is much easier for the device to be adhered to the circuit board.

In order to the make the objects, shapes, structural characteristics, and functions of the invention more comprehensible to the examiners, the embodiments are described in detail below with reference to the accompanying drawings.

### BRIEF DESCRIPTION OF THE DRAWINGS

FIG. 1 is a schematic view of the appearance of the sheet of the present invention.

FIG. 2 is a schematic view of the appearance of the device of the present invention.

FIG. 3 is a cross-sectional view of a right end of the device of the present invention.

FIG. 4 is a cross-sectional view of a left end of the device of the present invention.

### List of Reference Numerals

10 polymer-based sheet
11 H-shaped through-hole
12 strip-shaped sheet
21a left main structural electrode
21b right main structural electrode
22a, 23a left connection electrode
22b, 23b right connection electrode
20 insulating layer
22 first pair of electrodes
23 second pair of electrodes
24 cutting line

### DETAILED DESCRIPTION OF THE INVENTION

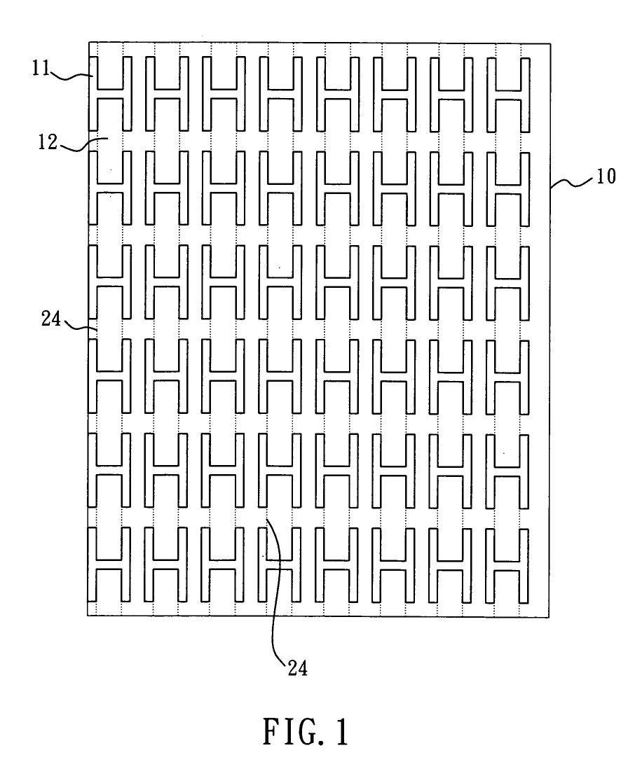

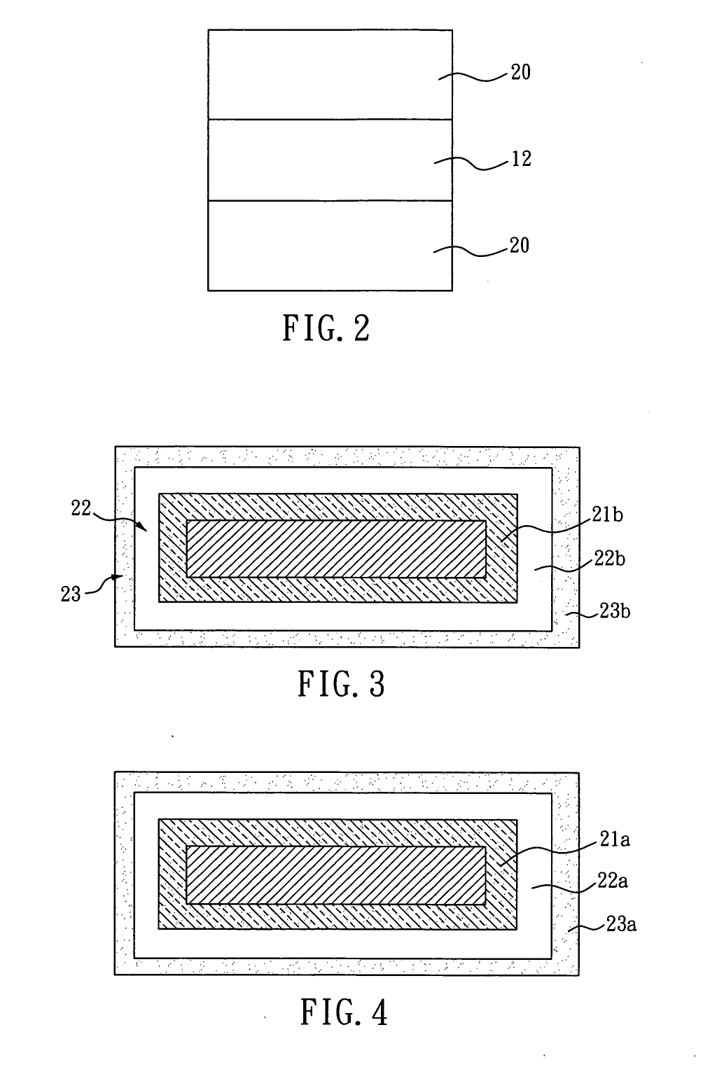

The present invention relates to an end electrode structure of a surface-mounted resettable over-current protection device. Referring to FIGS. 1, 2, 3, and 4, the structure is formed as follows. A polymer-based sheet 10 is punched with a mold for manufacturing a plurality of H-shaped through-holes 11 arranged at an equal interval, thereby forming several strip-shaped sheets 12. Then, referring to FIGS. 2, 3, and 4, through an ordinary through-hole manufacturing process of a printed circuit board, left connection electrodes 22a and 23a, and right connection electrodes 22b and 23b for connecting the left main structural electrode 21a and the right main structural electrode 21b are manufactured on five sides of each of the strip-shaped sheets. An insulating layer 20 is formed on each of four sides of the left main structural electrode 21a and the right main structural electrode 21b. Later, along the cutting lines 24 for shaping the structure, the strip-shaped sheets 12 are separated off, to form several over-current protection devices with five-sided electrodes.

Referring to FIGS. 2, 3, and 4, the five sides of the front end and the back end of the device are completely cladded by the left connection electrode 23a and the right connection electrode 23b. Thus, the left connection electrode 23a is used as a connection terminal for connecting other electrical apparatuses, and the right connection electrode 23b is used as a connection terminal for connecting other electrical apparatuses.

Referring to FIGS. 2, 3, and 4, the left connection electrode 22a and the right connection electrode 22b can be used to form a first pair of substantially symmetric electrodes 22, and the left connection electrode 23a and the right connection electrode 23b can be used to form a second pair of substantially symmetric electrodes 23.

As such, through the five-sided electrodes 22 and 23, it is much easier for the device to be adhered to a circuit board, thereby solving the problem in the prior art.

Referring to FIGS. 2 and 3 again, when the sheet 10 is divided into several strip-shaped devices, along the cutting lines 24× and 24y for shaping the structure, the strip-shaped sheet 12 is formed, thereby forming several over-current protection devices with five-sided electrodes.

In view of the above, the end electrode structure of a surface-mounted resettable over-current protection device is indeed provided with an unprecedented innovative structure. No similar products have been published in publications or the market. Therefore, the innovation of the device is absolutely undoubted. Additionally, since the prior art is not comparable to the unique feature and function of the present invention, the device is indeed more inventive than the prior art.

Only the preferable embodiment of the present invention is described above. However, the structural features of the present invention are not limited to the embodiment. The modifications and variations easily appreciated by those skilled in the art are all covered by the following claims of the present invention.

We claim:

1. A method for manufacturing an end electrode structure of a surface-mounted resettable over-current protection device, comprising the following steps:
forming a plurality of H-shaped through-holes separated at an equal interval and a plurality of strip-shaped sheets, wherein each of the strip-shaped sheets has an upper surface, a lower surface, a left surface, a right surface, a left end surface, and a right end surface;
forming a left main structural electrode on the upper surface, the lower surface, the left surface, the right surface, and the left end surface of each of the strip-shaped sheets;
depositing a first left connection electrode on the left main structural electrode;
depositing a second left connection electrode on the first left connection electrode;
forming a right main structural electrode on the upper surface, the lower surface, the left surface, the right surface, and the right end surface of each of the strip-shaped sheets;
depositing a first right connection electrode on the right main structural electrode;
depositing a second right connection electrode on the first right connection electrode;
forming an insulating layer on the upper surface, the lower surface, the left surface, and the right surface between the left main structural electrode and the right structural electrode of each of the strip-shaped sheets; and
cutting the polymer-based sheet along a plurality of cutting lines formed by the H-shaped through-holes, thereby forming a plurality of over-current protection devices with five sided electrodes on the left end surface and the right end surface of the strip-shaped sheets.

2. The method according to claim 1, wherein the step of forming H-shaped through-holes and the strip-shaped sheets is carried out by means of stamping.
